(19) United States
(12) Patent Application Publication
(10) Pub. No.: US 2017/0145247 A1
(43) Pub. Date: May 25, 2017

(54) PACKAGING COMPOSITION AND PACKAGING STRUCTURE EMPLOYING THE SAME

(71) Applicant: INDUSTRIAL TECHNOLOGY RESEARCH INSTITUTE, Hsinchu (TW)

(72) Inventors: Shou-yi HO, New Taipei City (TW); Kuo-Chan CHIOU, Tainan City (TW)

(73) Assignee: INDUSTRIAL TECHNOLOGY RESEARCH INSTITUTE, Hsinchu (TW)

(21) Appl. No.: 14/982,821

(22) Filed: Dec. 29, 2015

(30) Foreign Application Priority Data
Nov. 20, 2015 (TW) 104138434

(51) Int. Cl. C09D 133/14; C09D 139/04; H05K 1/18; C09D 7/12

(52) U.S. Cl. CPC C09D 133/14; C09D 7/1216; C09D 139/04; H05K 1/185; C08K 2003/2227

(57) ABSTRACT

A packaging composition and packaging structure employing the same are disclosed. The packaging composition includes: (a) 30-70 parts by weight of free radical polymerizable monomer, and (b) 30-70 parts by weight of prepolymer. In particular, the oligomer is a reaction product of polythiol compound and polyester oligomer having acrylate functional group.

### CROSS REFERENCE TO RELATED APPLICATIONS

The application is based on, and claims priority from, Taiwan Application Serial Number 104138434, filed on Nov. 20, 2015, the disclosure of which is hereby incorporated by reference herein in its entirety.

### TECHNICAL FIELD

The disclosure relates to a packaging composition and a packaging structure employing the same.

### BACKGROUND

In recent years, the development of flexible photoelectric devices (such as electronic paper or electronic cards) has proceeded quickly due to their advantages, which include being light-weight, thin, reusable, and portable. Along with miniaturization and high integration of flexible photoelectric devices, the density of heat generated from various components in the electronic devices has increased, and methods of releasing such heat to outside have been important.

Furthermore, due to the poor mechanical strength and poor scratch resistance of the flexible substrate or the electrode layer (such as Al electrode) of the flexible photoelectric devices, the flexible photoelectric devices would be damaged during reading or writing operation, thereby reducing the performance of image display and data storage. Therefore, there is a need to form a protective layer on the flexible photoelectric devices for improving the scratch resistance. The conventional protective layer, however, is apt to become peeled from the flexible photoelectric devices and reduce the heat dissipation capacity of the flexible photoelectric devices, due to the poor flexibility and thermal conductivity of the conventional protective layer.

### SUMMARY

According to embodiments of the disclosure, the disclosure provides a packaging composition including (a) 30-70 parts by weight of free radical polymerizable monomer; and, (b) 30-70 parts by weight of prepolymer, wherein the prepolymer is a reaction product of polythiol compound and polyester oligomer having at least one acrylate functional group. The (a) free radical polymerizable monomer and the (b) prepolymer are 100 parts by weight in total.

According to another embodiment of the disclosure, the disclosure also provides a packaging structure including a substrate; and, a packaging layer disposed on the substrate, wherein the packaging layer is a cured product of the aforementioned composition.

A detailed description is given in the following embodiments with reference to the accompanying drawings.

### BRIEF DESCRIPTION OF THE DRAWINGS

The disclosure can be more fully understood by reading the subsequent detailed description and examples with references made to the accompanying drawings, wherein:

FIG. 1 is a schematic view of a packaging structure according to an embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

The disclosure provides a packaging composition and a packaging structure employing the same. Since the specific molar ratio of the free radical polymerizable monomer and the prepolymer, the cured product of the packaging composition exhibits high thermal conductivity, hardness, and scratch resistance, thereby being suitable to serve as a packaging material for enhancing the heat-write-in resolution and reusability of the flexible photoelectric device (such as: flexible display device, electronic tickle card, or thermal addressable display (TAD) electronic paper). In addition, since the packaging composition of the disclosure includes a prepolymer (prepared from reacting thiol compound with the specific oligomer) (i.e. the thiol compound is reacted with the specific oligomer at first to obtain a prepolymer, and the prepolymer is then reacted with the free radical polymerizable monomer), the adhesion between the substrate (or electrode, such as aluminum, silver, or indium tin oxide (ITO)) and the cured product of the packaging composition can be improved, resulting in preventing the cured product of the packaging composition from peeling from the substrate or electrode.

The packaging composition of the disclosure can include (a) 30-70 parts by weight of free radical polymerizable monomer; and, (b) 30-70 parts by weight of prepolymer. In particular, the (a) free radical polymerizable monomer and the (b) prepolymer are 100 parts by weight in total. According to embodiments of the disclosure, when the content of (a) free radical polymerizable monomer is too low, the packaging composition would be not suitable for being used due to the increased viscosity. Conversely, when the content of (b) prepolymer is too low, the adhesion between the substrate (or electrode) and the cured product of the packaging composition would be deteriorated.

According to embodiments of the disclosure, the (a) free radical polymerizable monomer can be 2-carboxyethyl acrylate, ethoxylated bisphenol-A dimethacrylate, 2-phenylphenoxyethyl acrylate, dipropylene glycol diacrylate, dipentaerythritol penta-/hexa-acrylate, hexamethylene diacrylate (HDDA), triallyl-1,3,5-triazine-2,4,6-trione (TATATO), isobornyl acrylate, trimethylolpropane triacrylate (TMPTA), tri(propylene glycol) diacrylate (TPGDA), 4-Acryloylmorpholine (ACMO), N-vinyl-2-pyrrolidone (NVP), tetrahydrofurfuryl acrylate (THFA), or a combination thereof.

According to embodiments of the disclosure, the prepolymer can be a reaction product of polythiol compound and polyester oligomer having at least one acrylate functional group, wherein the molar ratio between the thiol functional group of the polythiol compound and the acrylate functional group of the polyester oligomer is from 2 to 4. When the molar ratio of the polythiol compound and the polyester oligomer having at least one acrylate functional group is too low, the reproducibility of the adhesion of the substrate and the cured product of the packaging composition is reduced. Conversely, when the molar ratio of the polythiol compound and the polyester oligomer having at least one acrylate functional group is too high, a cross-linked polymer would be obtained.

The polythiol compound can be pentaerythritol tetra(3-mercaptopropionate) (PETMP), pentaerythritol tetrakis(3-mercaptobutylate) (PETMB), glycol di(3-mercaptopropionate (GDMP), pentaerythritol tetramercaptoacetate (PETMA), trimethylolpropane trimercaptoacetate (TMPMA), trimethylolpropane tris(3-mercaptopropionate) (TMPMP), glycol dimercaptoacetate (GDMA), ethoxylated trimethylpropane tri(3-mercapto-propionate) (ETTMP)(with molecular weight of 700 or 1300), or a combination thereof. In addition, the polyester oligomer having at least one acrylate functional group can be urethane acrylate oligomer (such as aliphatic urethane methacrylate oligomer), epoxy acrylate oligomer (such as epoxy methacrylate oligomer), polyester acrylate oligomer, or a combination thereof.

According to embodiments of the disclosure, in order to enhance the thermal conductivity of the cured product of the packaging composition of the disclosure, the packaging composition of the disclosure can further include (c) 200-500 parts by weight of thermal conductive powder, wherein the thermal conductive powder can have a particle size between 0.5 μm and 10 μm. In particular, the thermal conductive powder can be boron nitride, aluminum oxide, aluminum nitride, magnesium nitride, zinc oxide, silicon carbide, beryllium oxide, diamond, tungsten carbide, or a combination thereof. According to an embodiment of the disclosure, the thermal conductive powder can be aluminum oxide in order to enhance the thermal conductivity, hardness, and bending resistance of the cured product of the packaging composition.

According to embodiments of the disclosure, the packaging composition of the disclosure can further include (d) 0.01-10 parts by weight of additive agent, such as initiator, stabilizer, defoamer, leveling agent, wetting agent, thixotropic agent, antioxidant, UV absorber, adhesion promoter, or a combination thereof. For example, the packaging composition of the disclosure can include a defoamer and/or a leveling agent in order to improve the flatness of the coating of the packaging composition and increase the write-in resolution. The initiator can be benzoyl peroxide, azobisisobutyronitrile, acetyl peroxide, t-butyl peracetate, cumyl peroxide, t-Butyl peroxide, t-butyl hydroperoxide, 1-hydroxycyclohexyl phenyl ketone, 2-hydroxy-2-methyl-1-phenyl-propan-1-one, or diphenyl(2,4,6-trimethylbenzoyl)phosphine oxide. The stabilizer can be pyrogallol, hydroquinone, or catechol. The defoamer can be silicon-containing organic compound or polyether (with a trade No. BYK-065, BYK-051, and BYK-392 sold by BYK Chemie German). The leveling agent can be silicon-containing organic compound or polyether (with a trade No. BYK-377, BYK325, and BYK-3510 sold by BYK Chemie German). The above additive agent are for example but not limited to.

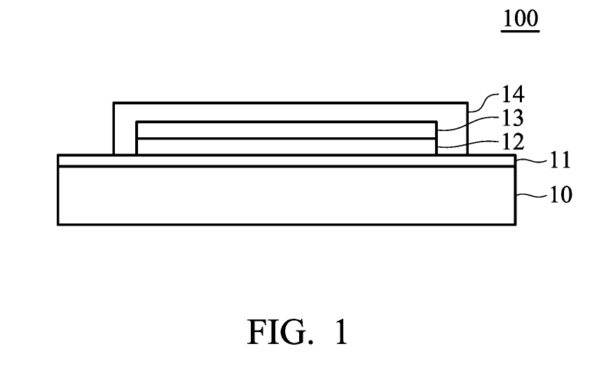

According to some embodiments of the disclosure, the disclosure also provides a packaging structure 100 including a substrate 10, an electronic element 12 disposed on the substrate 10, and a packaging layer 14 covering the electronic element 12, as shown in FIG. 1. In particular, the packaging layer 14 can be a cured product of the aforementioned packaging composition subjected to curing process. In addition, a first electrode 11 can be disposed between the electronic element 12 and the substrate 10, and a second electrode 13 can be disposed between the electronic element 12 and the packaging layer 14. The substrate 10 can be flexible substrate, such as polyimide (PI), polyethylene terephthalate (PET), polycarbonate (PC), polyethylene naphthalate (PEN), or a combination thereof. The first electrode 11 and second electrode 13 can be aluminum, silver, copper, or indium tin oxide, but not limited to.

FIG. 1 is a schematic view of a packaging structure according to an embodiment of the disclosure (for example but not limited to). According to embodiments of the disclosure, the electronic element 12 can be formed within the substrate 10, and the packaging layer 14 covers the substrate 10. Since the packaging composition of the disclosure includes the prepolymer prepared from the thiol compound, the adhesion between the substrate (or electrode) and the cured product of the packaging composition can be enhanced. According to embodiments of the disclosure, the electronic element can be, for example, an image display device, or a data storage device. In addition, the packaging structure of the disclosure can be applied in flexible photoelectric device (such as: flexible display device, electronic tickle card, or thermal addressable display (TAD) electronic paper).

According to embodiments of the disclosure, the packaging layer of the disclosure can be prepared by following steps: subjecting the packaging composition of the disclosure to a coating process, and then subjecting the obtained coating to a curing process. The coating process can be screen printing, spin coating, bar coating, blade coating, roller coating, or dip coating. In addition, the packaging layer is able to withstand a wide temperature range extending from about 50° C. to 200° C.

The following examples are intended to illustrate the disclosure more fully without limiting the scope, since numerous modifications and variations will be apparent to those skilled in this art.

Preparation of Prepolymer

### Preparation Example 1

Pentaerythritol tetra(3-mercaptopropionate) (PETMP) (27.5 mmol) and polyurethane acrylate oligomer (with a molecular weight of 2181 and having two acrylate functional groups) (13.76 mmol) were added into a reaction bottle. After mixing, 0.00434 g of azobisisobutyronitrile (AIBN) was added into the reaction bottle. After stirring at 70° C. for 5 min, 0.43 g of pyrogallol was added into the reaction bottle, obtaining the prepolymer (1) with a viscosity of 18180 cps.

### Preparation Example 2

Trimethylolpropane tris(3-mercaptopropionate) (TMPMP) (27.5 mmol) and polyurethane acrylate oligomer (with a molecular weight of 2181 and having two acrylate functional groups) (13.76 mmol) were added into a reaction bottle. After mixing, 0.00398 g of azobisisobutyronitrile (AIBN) was added into the reaction bottle. After stirring at 70° C. for 20 min, 0.3981 g of pyrogallol was added into the reaction bottle, obtaining the prepolymer (2) with a viscosity of 12348 cps.

### Preparation Example 3

Pentaerythritol tetra(3-mercaptopropionate) (PETMP) (46.72 mmol) and polyester acrylate oligomer (with a molecular weight of 642, and having one acrylate functional group) (46.72 mmol) were added into a reaction bottle. After mixing, 0.005283 g of azobisisobutyronitrile (AIBN) was added into the reaction bottle. After stirring at 60° C. for 30 min, 0.5283 g of pyrogallol was added into the reaction bottle, obtaining the prepolymer (3) with a viscosity of 3670 cps.

### Preparation Example 4

Ethoxylated trimethylpropane tri(3-mercapto-propionate) (ETTMP)(with a molecular weight of about 700) (46.72 mmol) and polyester acrylate oligomer (with a molecular weight of 642 and having one acrylate functional group) (46.72 mmol) were added into a reaction bottle. After mixing, 0.006271 g of azobisisobutyronitrile (AIBN) was added into the reaction bottle. After stirring at 60° C. for 30 min, 0.6271 g of pyrogallol was added into the reaction bottle, obtaining the prepolymer (4) with a viscosity of 7852 cps.

### Preparation Example 5

Glycol dimercaptoacetate (GDMA) (15.61 mmol) and epoxy acrylate oligomer (with a molecular weight of 3844 and having two acrylate functional groups) (46.72 mmol) were added into a reaction bottle. After mixing, 0.003372 g of azobisisobutyronitrile (AIBN) was added into the reaction bottle. After stirring at 70° C. for 10 min, 0.3372 g of pyrogallol was added into the reaction bottle, obtaining the prepolymer (5) with a viscosity of 57630 cps.

Packaging Composition

### Example 1

Triallyl-1,3,5-triazine-2,4,6-trione (TATATO), acrylic resin (with a trade No. of RSH, sold by Poly-Tech Co. Ltd.)(TATATO and RSH are 41 parts by weight in total, TATATO:RSH=6:1), 55 parts by weight of prepolymer (1), additive agent (including 3 parts by weight of photo-initiator, 0.1 parts by weight of leveling agent (BYK388), and 0.9 parts by weight of stabilizer (pyrogallol) were added into a reaction bottle. After stirring, a packaging composition was obtained. Next, coatings of the packaging composition were formed on the ITO electrode of a PET substrate and the aluminum electrode of another PET substrate respectively. After subjecting to UV-curing process, packaging layers (1) were obtained. The contents of components of Example 1 were shown in Table 1.

### Example 2

Example 2 was performed in the same manner as in Example 1 except that 300 parts by weight of aluminum oxide was additionally added into the reaction bottle to obtain a mixture. Next, the mixture was subjected to a rolling process several times, obtaining a packaging composition. Next, coatings of the packaging composition were formed on the ITO electrode of a PET substrate and the aluminum electrode of another PET substrate respectively. After subjecting to UV-curing process, packaging layers (2) were obtained. The contents of components of Example 2 are shown in Table 1.

### Example 3

Example 3 was performed in the same manner as in Example 2 except that 41 parts by weight of TATATO and RSH is substituted by 66 parts by weight of TATATO and RSH (TATATO:RSH=6:1), and 55 parts by weight of prepolymer (1) is substituted by 30 parts by weight of prepolymer (1), obtaining packaging layers (3). The contents of components of Example 3 are shown in Table 1.

### Example 4

Example 4 was performed in the same manner as in Example 2 except that 41 parts by weight of TATATO and RSH is substituted by 26 parts by weight of TATATO and RSH (TATATO:RSH=6:1), and 55 parts by weight of prepolymer (1) is substituted by 70 parts by weight of prepolymer (1), obtaining packaging layers (4). The contents of components of Example 4 are shown in Table 1.

### Comparative Example 1

Comparative Example 1 was performed in the same manner as in Example 1 except that 600 parts by weight of aluminum oxide was additionally added into the reaction bottle to obtain a mixture. Next, the mixture was subjected to a rolling process several times, obtaining a packaging composition. Next, coatings of the packaging composition were formed on the ITO electrode of a PET substrate and the aluminum electrode of another PET substrate respectively. After subjecting to UV-curing process, packaging layers (5) were obtained. The contents of components of Comparative Example 1 are shown in Table 1.

### Comparative Example 2

Comparative Example 2 was performed in the same manner as in Example 2 except that 55 parts by weight of prepolymer (1) is substituted by 17.02 parts by weight of pentaerythritol tetra(3-mercaptopropionate) (PETMP) and 37.98 parts by weight of polyurethane acrylate oligomer (with a molecular weight of 2181 and two acrylate functional groups), obtaining packaging layers (6). Namely, PETMP was reacted with TATATO and oligomer simultaneously, rather than reacted with oligomer in advance. The contents of components of Comparative Example 2 are shown in Table 1.

### Comparative Example 3

Comparative Example 3 was performed in the same manner as in Example 2 except that prepolymer (1) is substituted by polyurethane acrylate oligomer (with a molecular weight of 2181), obtaining packaging layers (7). The contents of components of Comparative Example 3 are shown in Table 1.

Next, the aluminum adhesion, ITO adhesion, hardness, thermal conductivity, flexibility of packaging layers (1)-(7) were measured, and the results are shown in Table 1. The adhesion was determined according to ASTM D3359 (with 3M Scotch Transparent Film Tape 600). The hardness was determined according to ASTM D3363. The flexibility was measured by taking opposite corners of the printed rectangles, and folding them to form a radius of curvature of 10 mm. After repeating the above step 10 times, the presence or absence of cracks was recorded (◯: absence of cracks; X presence of cracks). The thermal conductivity was determined according to ASTM E1461.

TABLE 1

| | TATATO | | additive | aluminum | | | | | |
|---|---|---|---|---|---|---|---|---|---|
| | and RSH(6:1) | prepolymer1 | agent | oxide powder | | | | thermal | |
| | (parts by | (parts by | (parts by | (parts by | adhesion | adhesion | | conductivity | |
| | weight) | weight) | weight) | weight) | (aluminum) | (ITO) | hardness | (w/mk) | flexibility |
| Example 1 | 41 | 55 | 4 | 0 | 5B | 5B | HB | 0.185 | ◯ |
| Example 2 | 41 | 55 | 4 | 300 | 5B | 5B | 4H | 1.134 | ◯ |
| Example 3 | 66 | 30 | 4 | 300 | 5B | 5B | 4H | 1.085 | ◯ |
| Example 4 | 26 | 70 | 4 | 300 | 5B | 5B | 4H | 1.087 | ◯ |
| Comparative | 41 | 55 | 4 | 600 | 5B | 5B | 6H | 1.501 | X |
| Example 1 | | | | | | | | | |
| Comparative | 41 | PETMP) | 4 | 300 | 0B | 0B | 4H | 1.032 | ◯ |
| Example 2 | | (17.02parts | | | | | | | |
| | | by weight of) | | | | | | | |
| | | and polyurethane | | | | | | | |
| | | acrylate | | | | | | | |
| | | oligomer | | | | | | | |
| | | (37.98parts | | | | | | | |
| | | by weight of) | | | | | | | |
| Comparative | 41 | polyurethane | 4 | 300 | 0B | 0B | 4H | 0.956 | |
| Example 3 | | acrylate | | | | | | | |
| | | oligomer | | | | | | | |
| | | (55parts | | | | | | | |
| | | by weight) | | | | | | | |

As shown in Table 1, since the packaging composition of the disclosure includes the prepolymer (preparing by reacting polythiol compound and polyester oligomer having at least one acrylate functional group), the adhesion between the substrate (or electrode, such as aluminum, silver, or indium tin oxide (ITO)) and the cured product of the packaging composition can be improved. In addition, when the packaging composition further includes a thermal conductive powder (such as: aluminum oxide powder), the cured product of the packaging composition has enhanced thermal conductivity. However, when the content of the thermal conductive powder of the packaging composition is too high (for example, the weight of the thermal conductive powder is more than 6 times than the total weight of free radical polymerizable monomer and prepolymer), the flexibility of the obtained packaging layer is deteriorated. In Comparative Example 2, polythiol compound was reacted with TATATO and polyester oligomer having an acrylate functional group simultaneously, rather than reacted with oligomer in advance as disclosed in Example 2. Therefore, the packaging layer of the Comparative Example 2 has relatively low adhesion.

Moreover, in Comparative Example 3, polyester oligomer having an acrylate functional group was directly reacted with TATATO in the absence of polythiol compound, rather than reacted with polythiol compound in advance as disclosed in Example 2. Therefore, the packaging layer of the Comparative Example 3 has relatively low adhesion.

### Example 5

Example 5 was performed in the same manner as in Example 2 except that prepolymer (1) is substituted by prepolymer (2), obtaining packaging layers (8). The contents of components of Example 5 were shown in Table 2.

### Example 6

Example 6 was performed in the same manner as in Example 5 except that 41 parts by weight of TATATO and RSH is substituted by 66 parts by weight of TATATO and RSH (TATATO:RSH=6:1), and 55 parts by weight of prepolymer (2) is substituted by 30 parts by weight of prepolymer (2), obtaining packaging layers (9). The contents of components of Example 6 are shown in Table 2.

### Example 7

Example 7 was performed in the same manner as in Example 5 except that 41 parts by weight of TATATO and RSH is substituted by 26 parts by weight of TATATO and RSH (TATATO:RSH=6:1), and 55 parts by weight of prepolymer (2) is substituted by 70 parts by weight of prepolymer (2), obtaining packaging layers (10). The contents of components of Example 7 are shown in Table 2.

### Comparative Example 4

Comparative Example 4 was performed in the same manner as in Example 5 except that 55 parts by weight of prepolymer (2) is substituted by 31.552 parts by weight of trimethylolpropane tris(3-mercaptopropionate) (TMPMP) and 41.45 parts by weight of polyurethane acrylate oligomer (with a molecular weight of 2181 and two acrylate functional groups), obtaining packaging layers (11). Namely, TMPMP was reacted with TATATO and oligomer simultaneously, rather than reacted with oligomer in advance. The contents of components of Comparative Example 4 are shown in Table 2.

### Example 8

Example 8 was performed in the same manner as in Example 2 except that prepolymer (1) is substituted by prepolymer (3), obtaining packaging layers (12). The contents of components of Example 8 are shown in Table 2.

### Example 9

Example 9 was performed in the same manner as in Example 8 except that 41 parts by weight of TATATO and RSH is substituted by 66 parts by weight of TATATO and RSH (TATATO:RSH=6:1), and 55 parts by weight of prepolymer (3) is substituted by 30 parts by weight of prepolymer (3), obtaining packaging layers (13). The contents of components of Example 9 are shown in Table 2.

### Example 10

Example 10 was performed in the same manner as in Example 8 except that 41 parts by weight of TATATO and RSH is substituted by 26 parts by weight of TATATO and RSH (TATATO:RSH=6:1), and 55 parts by weight of prepolymer (3) is substituted by 70 parts by weight of prepolymer (3), obtaining packaging layers (14). The contents of components of Example 10 are shown in Table 2.

### Comparative Example 5

Comparative Example 8 was performed in the same manner as in Example 8 except that 55 parts by weight of prepolymer (3) is substituted by 23.27 parts by weight of pentaerythritol tetra(3-mercaptopropionate) (PETMP) and 31.23 parts by weight of polyester acrylate oligomer (with a molecular weight of 642, and having one acrylate functional group), obtaining packaging layers (15). Namely, PETMP was reacted with TATATO and oligomer simultaneously, rather than reacted with oligomer in advance. The contents of components of Comparative Example 5 are shown in Table 2.

### Example 11

Example 11 was performed in the same manner as in Example 2 except that prepolymer (1) is substituted by prepolymer (4), obtaining packaging layers (16). The contents of components of Example 8 are shown in Table 2.

### Example 12

Example 12 was performed in the same manner as in Example 11 except that 41 parts by weight of TATATO and RSH is substituted by 61 parts by weight of TATATO and RSH (TATATO:RSH=6:1), and 55 parts by weight of prepolymer (4) is substituted by 35 parts by weight of prepolymer (4), obtaining packaging layers (17). The contents of components of Example 12 are shown in Table 2.

### Example 13

Example 13 was performed in the same manner as in Example 11 except that 41 parts by weight of TATATO and RSH is substituted by 31 parts by weight of TATATO and RSH (TATATO:RSH=6:1), and 55 parts by weight of prepolymer (4) is substituted by 65 parts by weight of prepolymer (4), obtaining packaging layers (18). The contents of components of Example 13 are shown in Table 2.

### Comparative Example 6

Comparative Example 6 was performed in the same manner as in Example 8 except that 55 parts by weight of prepolymer (4) is substituted by 28.68 parts by weight of ethoxylated trimethylpropane tri(3-mercapto-propionate) (ETTMP) and 26.32 parts by weight of polyester acrylate oligomer (with a molecular weight of 642, and having one acrylate functional group), obtaining packaging layers (19). Namely, ETTMP was reacted with TATATO and oligomer simultaneously, rather than reacted with oligomer in advance. The contents of components of Comparative Example 6 were shown in Table 2.

### Example 14

Example 14 was performed in the same manner as in Example 2 except that prepolymer (1) is substituted by prepolymer (5), obtaining packaging layers (20). The contents of components of Example 8 are shown in Table 2.

### Example 15

Example 15 was performed in the same manner as in Example 14 except that 41 parts by weight of TATATO and RSH is substituted by 61 parts by weight of TATATO and RSH (TATATO:RSH=6:1), and 55 parts by weight of prepolymer (5) is substituted by 35 parts by weight of prepolymer (5), obtaining packaging layers (21). The contents of components of Example 15 are shown in Table 2.

### Example 16

Example 16 was performed in the same manner as in Example 14 except that 41 parts by weight of TATATO and RSH is substituted by 31 parts by weight of TATATO and RSH (TATATO:RSH=6:1), and 55 parts by weight of prepolymer (5) is substituted by 65 parts by weight of prepolymer (5), obtaining packaging layers (22). The contents of components of Example 16 are shown in Table 2.

### Comparative Example 7

Comparative Example 7 was performed in the same manner as in Example 14 except that 55 parts by weight of prepolymer (5) is substituted by 6.07 parts by weight of glycol dimercaptoacetate (GDMA) and 48.93 parts by weight of epoxy acrylate oligomer (with a molecular weight of 3844 and two acrylate functional groups), obtaining packaging layers (23). Namely, GDMA was reacted with TATATO and oligomer simultaneously, rather than reacted with oligomer in advance. The contents of components of Comparative Example 7 are shown in Table 2.

### Comparative Example 8

Comparative Example 8 was performed in the same manner as in Example 14 except that 55 parts by weight of prepolymer (5) is substituted by 55 parts by weight of epoxy acrylate oligomer (with a molecular weight of 3844 and two acrylate functional groups), obtaining packaging layers (24). The contents of components of Comparative Example 8 are shown in Table 2.

Next, the aluminum adhesion, ITO adhesion, hardness, thermal conductivity, flexibility of packaging layers (8)-(24) were measured, and the results are shown in Table 2.

TABLE 2

| | TATATO | | additive | aluminum | | | | | |
|---|---|---|---|---|---|---|---|---|---|
| | and RSH(6:1) | prepolymer1 | agent | oxide powder | | | | thermal | |
| | (parts by | (parts by | (parts by | (parts by | adhesion | adhesion | | conductivity | |
| | weight) | weight) | weight) | weight) | (aluminum) | (ITO) | hardness | (w/mk) | flexibility |
| Example 5 | 41 | 55 | 4 | 300 | 5B | 5B | 4H | 1.101 | ◯ |
| Example 6 | 66 | 30 | 4 | 300 | 5B | 5B | 4H | 1.061 | ◯ |
| Example 7 | 26 | 70 | 4 | 300 | 5B | 5B | 4H | 1.079 | ◯ |
| Comparative | 41 | TMPMP) | 4 | 300 | 0B | 0B | 4H | 1.011 | ◯ |
| Example 4 | | (31.55parts | | | | | | | |
| | | by weight) and | | | | | | | |
| | | polyurethane | | | | | | | |
| | | acrylate | | | | | | | |
| | | oligomer | | | | | | | |
| | | (41.45parts | | | | | | | |
| | | by weight) | | | | | | | |
| Example 8 | 41 | 55 | 4 | 300 | 5B | 5B | 4H | 1.058 | ◯ |
| Example 9 | 66 | 30 | 4 | 300 | 5B | 5B | 4H | 0.989 | ◯ |
| Example 10 | 26 | 70 | 4 | 300 | 5B | 5B | 4H | 1.021 | ◯ |
| Comparative | 41 | PETMP | 4 | 300 | 0B | 0B | 4H | 1.051 | ◯ |
| Example 5 | | (23.27parts | | | | | | | |
| | | by weight) | | | | | | | |
| | | and polyester | | | | | | | |
| | | acrylate | | | | | | | |
| | | oligomer | | | | | | | |
| | | (31.23parts | | | | | | | |
| | | by weight) | | | | | | | |
| Example 11 | 41 | 55 | 4 | 300 | 5B | 5B | 4H | 0.978 | ◯ |
| Example 12 | 61 | 35 | 4 | 300 | 5B | 5B | 4H | 1.004 | ◯ |
| Example 13 | 31 | 65 | 4 | 300 | 5B | 5B | 4H | 1.036 | ◯ |
| Comparative | 41 | ETTMP | 4 | 300 | 0B | 0B | 4H | 1.004 | ◯ |
| Example 6 | | (28.68 parts | | | | | | | |
| | | by weight) | | | | | | | |
| | | and polyester | | | | | | | |
| | | acrylate | | | | | | | |
| | | oligomer | | | | | | | |
| | | (26.32 parts | | | | | | | |
| | | by weight) | | | | | | | |
| Example 14 | 41 | 55 | 4 | 300 | 5B | 5B | 4H | 1.115 | ◯ |
| Example 15 | 61 | 35 | 4 | 300 | 5B | 5B | 4H | 1.054 | ◯ |
| Example 16 | 31 | 65 | 4 | 300 | 5B | 5B | 4H | 1.043 | ◯ |
| Comparative | 41 | GDMA | 4 | 300 | 0B | 0B | 4H | 1.055 | ◯ |
| Example 7 | | (6.07parts | | | | | | | |
| | | by weight) and | | | | | | | |
| | | epoxy acrylate | | | | | | | |
| | | oligomer | | | | | | | |
| | | (48.93parts | | | | | | | |
| | | by weight) | | | | | | | |
| Comparative | 41 | epoxy acrylate | 4 | 300 | 0B | 0B | 4H | 1.041 | ◯ |
| Example 8 | | oligomer | | | | | | | |
| | | (55parts | | | | | | | |
| | | by weight) | | | | | | | |

As shown in Table 2, since the packaging composition of the disclosure includes the prepolymer (preparing by reacting polythiol compound and polyester oligomer having an acrylate functional group), the adhesion between the substrate (or electrode, such as aluminum, silver, or indium tin oxide (ITO)) and the cured product of the packaging composition can be improved.

In addition, in Comparative Examples 4-7, polythiol compound was reacted with TATATO and polyester oligomer having an acrylate functional group simultaneously, rather than reacted with oligomer in advance as disclosed in Examples of the disclosure. Therefore, the packaging layer of the Comparative Examples 4-7 has relatively low adhesion.

Moreover, in Comparative Example 8, polyester oligomer having an acrylate functional group was directly reacted with TATATO in the absence of polythiol compound, rather than reacted with polythiol compound in advance as disclosed in Examples of the disclose. Therefore, the packaging layer of the Comparative Example 8 has relatively low adhesion. Accordingly, due to the addition of the prepolymer prepared from the polyester oligomer having an acrylate functional group and polythiol compound and the free radical polymerizable monomer with a specific ratio between the prepolymer and the free radical polymerizable monomer, the cured product of the packaging composition of the disclosure exhibits high thermal conductivity, hardness, scratch resistance, and improved adhesion, thereby being suitable to serve as a packaging material for enhancing the heat-write-in resolution and reusability of the flexible photoelectric device (such as: flexible display device, electronic tickle card, or thermal addressable display (TAD) electronic paper).

It will be clear that various modifications and variations can be made to the disclosed methods and materials. It is intended that the specification and examples be considered as exemplary only, with the true scope of the disclosure being indicated by the following claims and their equivalents.

What is claimed is:

1. A packaging composition, comprising:
(a) 30-70 parts by weight of free radical polymerizable monomer; and
(b) 30-70 parts by weight of prepolymer, wherein the prepolymer is a reaction product of polythiol compound and polyester oligomer having at least one acrylate functional group, wherein the (a) free radical polymerizable monomer and the (b) prepolymer are 100 parts by weight in total.

2. The packaging composition as claimed in claim 1, wherein the (a) free radical polymerizable monomer2-carboxyethyl acrylate, ethoxylated bisphenol-A dimethacrylate, 2-phenylphenoxyethyl acrylate, dipropylene glycol diacrylate, dipentaerythritol penta-/hexa-acrylate, hexamethylene diacrylate, isobornyl acrylate, triallyl-1,3,5-triazine-2,4,6-trione, trimethylolpropane triacrylate, tri(propylene glycol) diacrylate, 4-Acryloylmorpholine, N-vinyl-2-pyrrolidone, tetrahydrofurfuryl acrylate, or a combination thereof.

3. The packaging composition as claimed in claim 1, wherein the polythiol compound is pentaerythritol tetra(3-mercaptopropionate), pentaerythritol tetrakis(3-mercaptobutylate), glycol di(3-mercaptopropionate, pentaerythritol tetramercaptoacetate, trimethylolpropane trimercaptoacetate, trimethylolpropane tris(3-mercaptopropionate), glycol dimercaptoacetate, ethoxylated trimethylpropane tri(3-mercapto-propionate), or a combination thereof.

4. The packaging composition as claimed in claim 1, wherein the polyester oligomer having at least one acrylate functional group is urethane acrylate oligomer, urethane acrylate oligomer, polyester acrylate oligomer, or a combination thereof.

5. The packaging composition as claimed in claim 1, further comprising:
(c) 200-500 parts by weight of thermal conductive powder.

6. The packaging composition as claimed in claim 5, wherein the (c) thermal conductive powder comprises boron nitride, aluminum oxide, aluminum nitride, magnesium nitride, zinc oxide, silicon carbide, beryllium oxide, diamond, tungsten carbide, or a combination thereof.

7. The packaging composition as claimed in claim 1, further comprising:
(d) 0.01-10 parts by weight of additive agent.

8. The packaging composition as claimed in claim 7, wherein the (d) additive agent comprises initiator, stabilizer, defoamer, leveling agent, wetting agent, thixotropic agent, antioxidant, UV absorber, adhesion promoter, or a combination thereof.

9. A packaging structure, comprising:
a substrate; and
a packaging layer disposed on the substrate, wherein the packaging layer is a cured product of the packaging composition as claimed in claim 1.

10. The packaging structure as claimed in claim 9, further comprising:
an electronic element disposed on the substrate, wherein the packaging layer covers the electronic element.

11. The packaging structure as claimed in claim 9, wherein the substrate is a flexible substrate.
